(19) United States
(12) Patent Application Publication
(10) Pub. No.: US 2026/0291492 A1
(43) Pub. Date: Sep. 24, 2026

(54) POWER BJT DEVICE WITH SINGLE PULSE CURRENT STRONG TURN-OFF CAPABILITY, CIRCUIT BREAKER, AND METHOD

(71) Applicant: XI'AN JIAOTONG UNIVESTITY, XI'an Shaanxi (CN)

(72) Inventors: Yifei WU, Xi'an (CN); Yi WU, Xi'an (CN); Tianpei SHAN, Xi'an (CN); Yu XIAO, Xi'an (CN); Hongwei LIU, Xi'an (CN)

(21) Appl. No.: 19/565,943

(22) Filed: Mar. 13, 2026

(30) Foreign Application Priority Data
Mar. 18, 2025 (CN) 2025103222505

(51) Int. Cl. H03K 17/30; H03K 17/06; H03K 17/0812; H10D 10/40

(52) U.S. Cl. CPC H03K 17/30; H03K 17/06; H03K 17/08126; H10D 10/40; H03K 2017/066; H03K 2217/0063; H03K 2217/0081

(57) ABSTRACT

A power BJT device with single pulse current strong turn-off capability, a circuit breaker, and a method are disclosed, in the power BJT device with single pulse current strong turn-off capability, an N-type drift region is laminated on a substrate, a P-type base region is laminated on the N-type drift region, at least one N-type region is arranged on the P-type base region, a collector is arranged on the N-type substrate as a power lead-out electrode, an emitter is arranged on the N-type region as a power lead-out electrode, a base is arranged on the P-type base region without contacting the N-type region as a control lead-out electrode, and a drive circuit is connected with the base to control the turn-on and turn-off of the power BJT device.

### CROSS-REFERENCE TO RELATED APPLICATION

This application claims priority from the Chinese patent application 2025103222505 filed Mar. 18, 2025, the content of which is incorporated herein in the entirety by reference.

### TECHNICAL FIELD

The present disclosure relates to the technical field of power semiconductor devices, in particular to a power BJT device with single pulse current strong turn-off capability.

### BACKGROUND OF THE INVENTION

DC circuit breakers are the key DC equipment for quickly isolating DC faults. Due to the integration of the advantages of both fast mechanical switches and power electronic switches, the hybrid DC circuit breaker has emerged as the mainstream solution for achieving rapid and high-capacity DC interruption. Among these components, the power electronic switch serves as the core part for interrupting fault currents. Power electronic switches are constructed from power semiconductor devices. By employing a series-parallel combination of fully-controlled power semiconductor devices (abbreviated as fully-controlled devices) and adopting a modular design for power electronic switches, the interruption capacity of the power electronic switches can be enhanced.

Currently, the fully-controlled devices predominantly utilized in engineering practices of hybrid DC circuit breakers include Insulated Gate Bipolar Transistors (IGBTs), Metal Oxide Semiconductor Field Effect Transistors (MOSFETs), and Integrated Gate-Commutated Thyristors (IGCTs). Among these, IGBT devices are widely adopted in engineering applications due to their excellent surge current capability and turn-off capability. However, the complex manufacturing process and high cost of IGBT devices result in suboptimal technical and economic performance of power electronic switches, thereby hindering the further promotion and application of hybrid circuit breaker solutions.

Under the operating conditions of the hybrid DC circuit breakers, the fully-controlled devices of the power electronic switches only need to turn off high overload ratio currents once and do not require short-circuit withstand capability. Meanwhile, as buffer circuits and Metal Oxide Varistors (MOVs) are configured to enhance the turn-off reliability of the devices, the turn-off stress experienced by the fully-controlled devices during the turn-off process is relatively low. Considering the device lifespan and reliability, constrained by their characteristics, the current turn-off performance of the existing IGBT devices is difficult to achieve substantial improvement. In comparison to the IGBT devices, Bipolar Junction Transistors (BJTs) exhibit higher cell power density, simpler manufacturing processes, no risk of gate oxide breakdown, and a more flexible and controllable turn-off process. It is anticipated that BJTs can significantly enhance the technical and economic performance of the power electronic switches. However, due to the limitation of excessively high drive circuit power requirements, BJT devices are not suitable for converter applications, especially high-voltage and large-capacity commercial BJT devices. When considering repetitive pulse operation conditions, traditional BJT devices typically employ voltage-source drive circuits, which are not suitable for the base drive current injection and extraction required in single-pulse current operation conditions.

The information disclosed in the Background section is only for enhancement of understanding of the background of the disclosure and therefore may contain information that does not constitute the prior art that is well known to those of ordinary skill in the art.

### SUMMARY

In response to the shortcomings or drawbacks of the prior art, a power BJT device with single pulse current strong turn-off capability, a circuit breaker, and a method are provided, which are suitable for base drive current injection and extraction under single-pulse current operation conditions.

The objective of the present disclosure is achieved by the following technical solution.

A power BJT device with single pulse current strong turn-off capability includes,
an N-type substrate,
an N-type drift region laminated on the substrate,
a P-type base region laminated on the N-type drift region,
at least one N-type region arranged on the P-type base region,
a collector arranged on the N-type substrate as a power lead-out electrode,
an emitter arranged on the N-type region as a power lead-out electrode,
a base arranged on the P-type base region without contacting the N-type region as a control lead-out electrode, and
a drive circuit connected with the base to control the turn-on and turn-off of a power BJT device.

In the power BJT device with single pulse current strong turn-off capability, the drive circuit operates according to an external control signal, which is an optical signal or an electrical signal.

In the power BJT device with single pulse current strong turn-off capability, the drive circuit includes a base injection circuit and a base reverse bias circuit connected in parallel.

In the power BJT device with single pulse current strong turn-off capability, when the power BJT device is subjected to a voltage greater than a threshold voltage, if the base injection circuit is connected and the base reverse bias circuit is disconnected, the power BJT device enters a turn-on state; if the base injection circuit is disconnected and the base reverse bias circuit is disconnected, the power BJT device enters a turn-off state; if the base injection circuit is disconnected and the base reverse bias circuit is connected, the power BJT device remains in the turn-off state with enhanced blocking voltage capability.

In the power BJT device with single pulse current strong turn-off capability, the base injection circuit and the base reverse bias circuit are restricted from being simultaneously connected.

In the power BJT device with single pulse current strong turn-off capability, the base injection circuit includes,
a pre-storage capacitor C1 and a device Q1 connected in series, the device Q1 being either a half-controlled power electronic device or a fully-controlled power electronic device,
a pre-storage capacitor C2 and a device Q2 connected in series, which are connected in parallel with the pre-storage capacitor C1 and the device Q1 connected in series, the device Q2 being a fully-controlled power electronic device,
a diode D1, connected in parallel with the pre-storage capacitor C1 and the device Q1 connected in series,
an inductor L1, connected with the device Q1, the device Q2 and the diode D1,
a diode D2 and a resistor R1 connected in series, which are connected in parallel with the inductor L1, and
a device Q3, connected in series with the inductor L1, the device Q3 being a fully-controlled power electronic device.

In the power BJT device with single pulse current strong turn-off capability, the base reverse bias circuit includes a device Q4, a resistor R2 and a pre-storage capacitor C3 connected in series, the device Q4 being either a half-controlled power electronic device or a fully-controlled power electronic device.

In the power BJT device with single pulse current strong turn-off capability, the fully-controlled power electronic device includes an IGBT or MOSFET.

A hybrid direct current circuit breaker includes the power BJT device with single pulse current strong turn-off capability.

An interruption method for the power BJT device with single pulse current strong turn-off capability includes the following steps,
connecting the device Q1 and the device Q3 simultaneously, allowing the pre-storage capacitor C1 to discharge through the inductor L1, enabling a base drive current to rise to a predetermined base injection current maximum threshold;
when a current of the inductor L1 reaches a half-wave peak, disconnecting the device Q1 and the device Q2 while keeping the device Q3 connected to enable freewheeling of the base drive current through the diode D1,
when a current of the inductor L1 falls to the lowest base injection current minimum threshold required for the power BJT device to remain in the turn-on state, keeping the device Q1 disconnected and the device Q2 connected, allowing the pre-storage capacitor C2 to discharge through the inductor L1, enabling the base drive current to slowly rise to the base injection current maximum threshold;
repeating switching several times according to the fluctuating state of the base drive current during the period that the power BJT device remains in the turn-on state; and
when the power BJT device turns off the current, disconnecting the device Q1, the device Q2, and the device Q3, connecting the device Q4, allowing the pre-storage capacitor C3 to continuously applies a reverse bias voltage at the base through the resistor R2 and the device Q4, enabling the current of the inductor L1 to be dissipated through the diode D2 and the resistor R1.

Compared with the prior art, the beneficial effects brought about by the present disclosure are:
this disclosure is specifically designed for single-pulse high-current turn-off operating conditions, and the drive circuit does not need to consider long-term power consumption issues. Due to the characteristics of IGBTs and IGCTs, there is a bottleneck in their single-pulse high-current turn-off capability, which cannot be fundamentally overcome with the current technological advancements. In contrast, power BJT devices exhibit superior performance in both cost-effectiveness and size due to their higher power density per unit and simpler device structure.

The description is only an overview of the technical solution of the disclosure, and in order to make the technical means of the present disclosure more clearly understood, to the extent that those skilled in the art can implement it according to the contents of the specification, and to make the above and other objectives, features and advantages of the present disclosure more clearly understood, specific embodiments of the present disclosure will be described below.

### BRIEF DESCRIPTION OF DRAWINGS

Various additional advantages and benefits of the present disclosure will become apparent to those of ordinary skill in the art upon reading the following detailed description of the preferred embodiments. The drawings of the specification are only for the purpose of illustrating preferred embodiments and are not to be construed as limiting the scope of the disclosure. It is obvious that the drawings described below are merely some embodiments of the present disclosure, for those of ordinary skill in the art, other drawings can also be obtained according to these drawings without paying creative effort. Also, like reference numerals refer to like parts throughout the drawings.

In the drawings:

FIG. 1 is a structural schematic diagram of a common emitter of a power BJT device;

FIG. 2 is a structural schematic diagram of the power BJT device;

FIG. 3 is a cell structure diagram of the power BJT device;

FIG. 4 is a topological diagram of a drive circuit of the power BJT device;

FIGS. 5A-D are logical diagrams of the drive circuit operation of the power BJT device;

FIG. 6 is a working waveform diagram of the drive circuit of the power BJT device;

FIG. 7 is a topological diagram of a hybrid DC circuit breaker of the power BJT device;

FIG. 8 is a schematic diagram of the interruption principle of the hybrid DC circuit breaker of the power BJT device;

FIG. 9 is a topological diagram of a bidirectional power electronic interruption assembly of the power BJT device; and

FIG. 10 is a schematic diagram of the turn-off principle of a power electronic switch of the power BJT device.

The present disclosure is further explained below with reference to the accompanying drawings and examples.

### DETAILED DESCRIPTION OF THE INVENTION

Specific embodiments of the disclosure will be described in more detail below with reference to the accompanying drawings. While specific embodiments of the disclosure are illustrated in the accompanying drawings, it should be understood that the disclosure may be embodied in various forms and should not be construed as limited to the embodiments set forth herein. Rather, these embodiments are provided so that the present disclosure will be more fully understood, and will fully convey the scope of the disclosure to those skilled in the art.

It should be noted that certain terms are used throughout the specification and claims to refer to certain components. It will be appreciated by those skilled in the art that different terms may be used to refer to the same component. The present specification and claims do not use differences in terms as a means of distinguishing components, but use differences in functions of components as a criterion for distinguishing. “Include” or “including”, as referred to throughout the specification and claims, is an open-ended language that is to be interpreted as “including, but not limited to”. The following description describes preferred embodiments for carrying out the disclosure, but the description is for the purpose of general principles of the specification and is not intended to limit the scope of the disclosure. The scope of the disclosure is defined by the appended claims.

In order to facilitate an understanding of the embodiments of the present disclosure, several specific embodiments will now be further described by way of example with reference to the accompanying drawings, and each of the accompanying drawings does not constitute a limitation on the embodiments of the present disclosure.

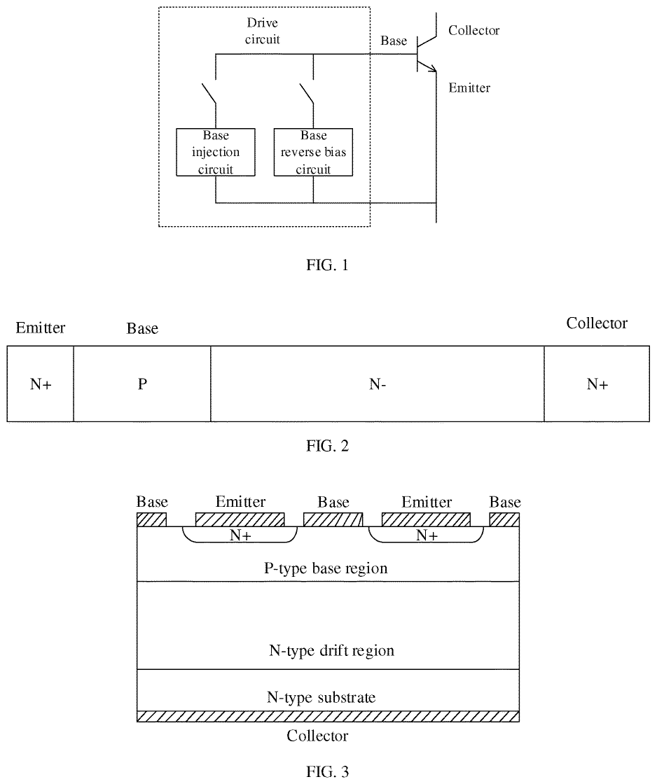

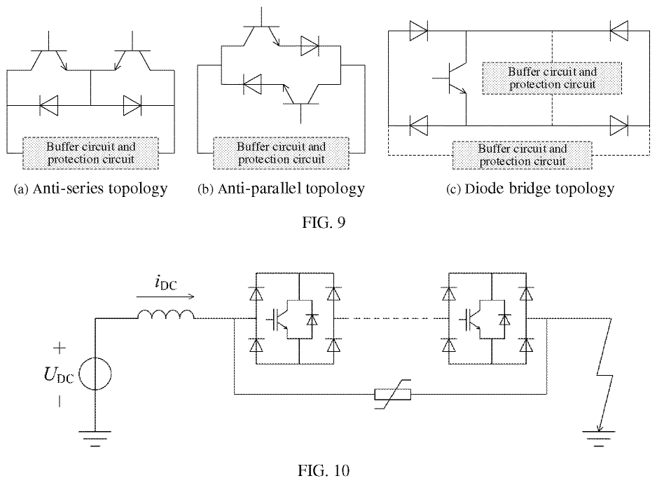

For better understanding, as shown in FIGS. 1-10, the power BJT device with single pulse current strong turn-off capability includes,
an N-type substrate,
an N-type drift region laminated on the substrate,
a P-type base region laminated on the N-type drift region,
at least one N-type region arranged on the P-type base region,
a collector arranged on the N-type substrate as a power lead-out electrode,
an emitter arranged on the N-type region as a power lead-out electrode,
a base arranged on the P-type base region without contacting the N-type region as a control lead-out electrode, and
a drive circuit connected with the base to control the turn-on and turn-off of a power BJT device.

In a preferred embodiment of the power BJT device with single pulse current strong turn-off capability, the drive circuit operates according to an external control signal, which is an optical signal or an electrical signal.

In a preferred embodiment of the power BJT device with single pulse current strong turn-off capability, the drive circuit includes a base injection circuit and a base reverse bias circuit connected in parallel.

In a preferred embodiment of the power BJT device with single pulse current strong turn-off capability, when the power BJT device is subjected to a voltage greater than a threshold voltage, if the base injection circuit is connected and the base reverse bias circuit is disconnected, the power BJT device enters a turn-on state; if the base injection circuit is disconnected and the base reverse bias circuit is disconnected, the power BJT device enters a turn-off state; if the base injection circuit is disconnected and the base reverse bias circuit is connected, the power BJT device remains in the turn-off state with enhanced blocking voltage capability.

In a preferred embodiment of the power BJT device with single pulse current strong turn-off capability, the base injection circuit and the base reverse bias circuit are restricted from being simultaneously connected.

In a preferred embodiment of the power BJT device with single pulse current strong turn-off capability, the base injection circuit includes,
a pre-storage capacitor C1 and a device Q1 connected in series, the device Q1 being either a half-controlled power electronic device or a fully-controlled power electronic device,
a pre-storage capacitor C2 and a device Q2 connected in series, which are connected in parallel with the pre-storage capacitor C1 and the device Q1 connected in series, the device Q2 being a fully-controlled power electronic device,
a diode D1, connected in parallel with the pre-storage capacitor C1 and the device Q1 connected in series,
an inductor L1, connected with the device Q1, the device Q2 and the diode D1,
a diode D2 and a resistor R1 connected in series, which are connected in parallel with the inductor L1, and
a device Q3, connected in series with the inductor L1, the device Q3 being a fully-controlled power electronic device.

In the preferred embodiment of the power BJT device with single pulse current strong turn-off capability, the base reverse bias circuit includes a device Q4, a resistor R2 and a pre-storage capacitor C3 connected in series, the device Q4 being either a half-controlled power electronic device or a fully-controlled power electronic device.

In a preferred embodiment of the power BJT device with single pulse current strong turn-off capability, the fully-controlled power electronic device includes an IGBT or MOSFET.

A hybrid direct current circuit breaker includes the power BJT device with single pulse current strong turn-off capability.

An interruption method for the power BJT device with single pulse current strong turn-off capability includes the following steps,
the device Q1 and the device Q3 are simultaneously connected, the pre-storage capacitor C1 is allowed to discharge through the inductor L1, enabling a base drive current to rise to a predetermined base injection current maximum threshold;
when a current of the inductor L1 reaches a half-wave peak, the device Q1 and the device Q2 are disconnected while keeping the device Q3 connected to enable freewheeling of the base drive current through the diode D1,
when a current of the inductor L1 falls to the lowest base injection current minimum threshold required for the power BJT device to remain in the turn-on state, the device Q1 is kept disconnected and the device Q2 is kept connected, the pre-storage capacitor C2 is allowed to discharge through the inductor L1, enabling the base drive current to slowly rise to the base injection current maximum threshold;
switching is repeated several times according to the fluctuating state of the base drive current during the period that the power BJT device remains in the turn-on state; and
when the power BJT device turns off the current, the device Q1, the device Q2, and the device Q3 are disconnected, the device Q4 is connected, the pre-storage capacitor C3 is allowed to continuously apply a reverse bias voltage at the base through the resistor R2 and the device Q4, enabling the current of the inductor L1 to be dissipated through the diode D2 and the resistor R1.

In one embodiment, FIG. 1 is a common emitter structure of a BJT device. The collector and emitter are the power lead-out electrodes and the base is the control lead-out electrode. The base is connected with a drive circuit which controls the turn-on and turn-off of the BJT device. The drive circuit is constituted by a base injection circuit and a base reverse bias circuit connected in parallel. The drive circuit operates according to an external control signal, which may be an optical signal or an electrical signal. The drive circuit generally requires externally provided power supply.

When the device is subjected to a voltage greater than a threshold voltage, if the base injection circuit is connected and the base reverse bias circuit is disconnected, the BJT device enters a turn-on state; if the base injection circuit is disconnected and the base reverse bias circuit is disconnected, the BJT device enters a turn-off state; if the base injection circuit is disconnected and the base reverse bias circuit is connected, the BJT device remains in the turn-off state with enhanced blocking voltage capability; the case where the base injection circuit and the base reverse bias circuit are simultaneously connected is not allowed to occur.

In one embodiment, a full-wafer chip of the power BJT device is annularly arranged from cells. The power BJT device with single pulse current strong turn-off capability consists of the full-wafer chip and an integrated drive circuit.

FIG. 4 is a topological diagram of a drive circuit of the power BJT device. The device Q1 can be a half-controlled power electronic device or a fully-controlled power electronic device such as a thyristor, an IGBT, an MOSFET, etc., with a device package type being a low-voltage discrete device; the device Q2, the device Q3, and the device Q4 are a parallel combination of fully-controlled power electronic devices, such as an IGBT, an MOSFET, etc., whose device package type is a low-voltage discrete device; C1, C2, C3 are pre-storage capacitors; L1 is an inductor; D1 and D2 are diodes; R1 and R2 are resistors. Wherein, the capacitor C1 is characterized by low capacitance and high voltage withstanding capability, and the capacitor C2 is characterized by high capacitance and low voltage withstanding capability. The drive circuit employs a current-source-type turn-on method. Compared to the conventional voltage source-type turn-on mode, it requires less drive energy, resulting in lower cost and smaller size of the drive circuit.

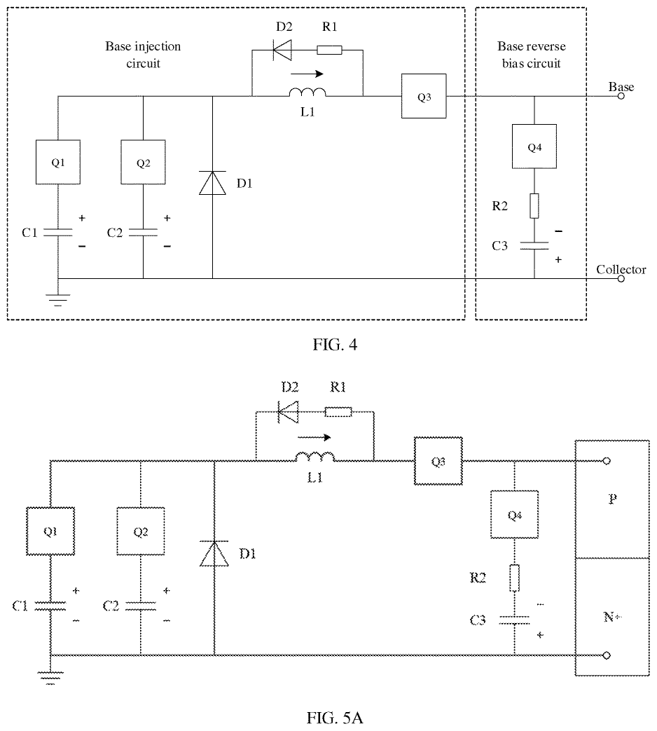

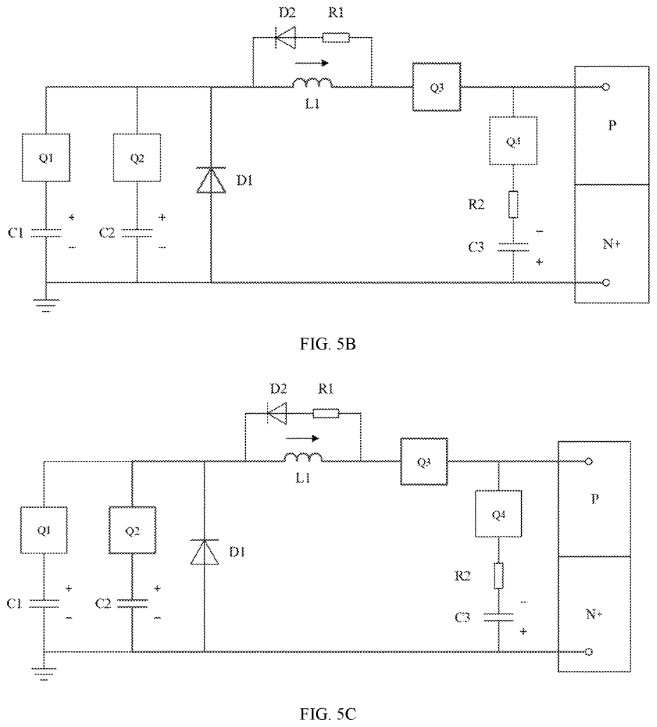

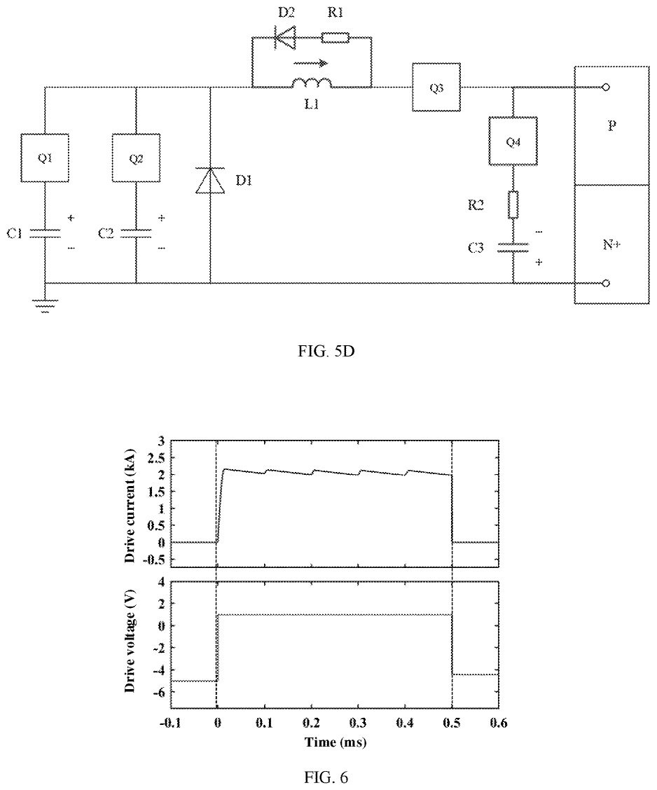

During the turn-on process of the BJT device:
(1) The devices Q1 and Q3 are connected simultaneously, the capacitor C1 is rapidly discharged through L1, and the base drive current rises to the specified base injection current maximum threshold in a very short time. This process is shown in FIG. 5A, corresponding to the waveform in the 0~0.01 ms time interval in FIG. 6.
(2) When the current of L1 reaches a half-wave peak, Q1 and device Q2 are disconnected, the device Q3 is kept connected, and the base drive current is freewheeled through the diode D1. During this time, the drive current will slowly drop due to the presence of the equivalent resistance in the freewheeling path. This process is shown in FIG. 5B, corresponding to the waveform in the 0.01~0.1 ms time interval in FIG. 6.
(3) When the current of L1 falls to the lowest base injection current minimum threshold required for the power BJT device to remain in the turn-on state, the device Q1 is kept disconnected, the device Q2 is kept connected, the capacitor C2 is slowly discharged through L1, and the base drive current slowly rises to the base injection current maximum threshold. This process is shown in FIG. 5C, corresponding to the waveform in the 0.1~0.11 ms time interval in FIG. 6.
(4) The above processes (2) and (3) can be repeatedly switched several times according to the fluctuating state of the base drive current during the period that the power BJT device remains in the turn-on state, corresponding to the waveform in the 0.11~0.5 ms time interval in FIG. 6.
(5) When the power BJT device turns off the current, the devices Q1, Q2, and Q3 are disconnected and the device Q4 is connected. C3 continuously applies a reverse bias voltage at the base through R2 and Q4, and the current of L1 is rapidly dissipated through D2 and R1, corresponding to the waveforms in the −0.1~0 ms and 0.5~0.6 ms time intervals in FIG. 6.

The power BJT device described possesses the capability of turning off high single-pulse currents, offering higher power density and lower cost and size. Unlike conventional power devices that are adapted for multi-pulse periodic operating conditions, this power BJT device is specifically designed for single-pulse high-current turn-off operating conditions. Consequently, the drive circuit does not need to account for long-term power consumption issues. Due to the characteristics of IGBTs and IGCTs, there is a bottleneck in their single-pulse high-current turn-off capability, which cannot be fundamentally overcome with the current technological advancements. In contrast, power BJT devices exhibit superior performance in both cost-effectiveness and size due to their higher power density per unit and simpler device structure.

The power BJT device has single pulse high current turn-off capability, higher device power density, lower device cost and volume. Unlike conventional power devices adapted for multi-pulse periodic operation, the described power BJT devices are specifically designed for single-pulse high-current off operation. Thus, the drive circuit does not have to take into account long-term power consumption issues. Since the device characteristics of IGBT, IGCT determine its single pulse high current turn-off capability to be bottlenecked, the state-of-the-art cannot achieve an essential breakthrough. Power BJT devices perform better in terms of both economics and volume due to higher specific power density and simpler device structure.

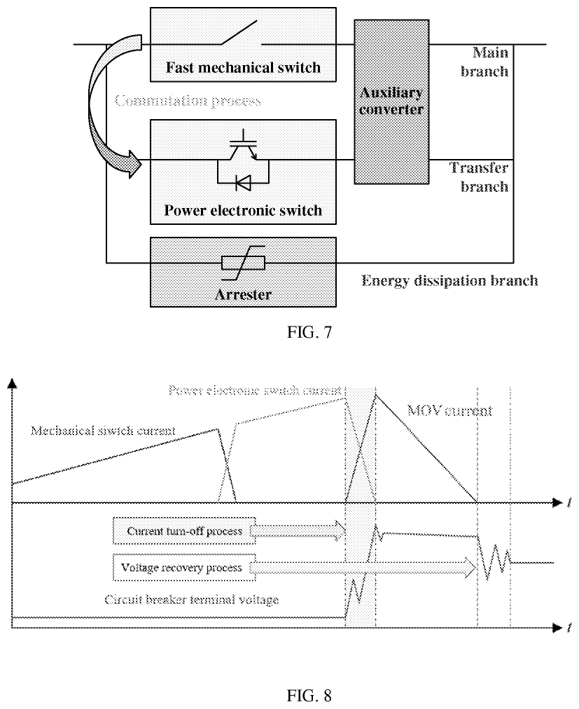

The applicable scenario of this disclosure can include hybrid DC circuit breakers. The basic topological structure of a hybrid DC circuit breaker is illustrated in FIG. 7. It often requires the installation of an additional auxiliary converter to achieve current transfer from the main branch. It primarily consists of key components such as a fast mechanical switch, an auxiliary converter, and a power electronic switch. Based on the commutation method, hybrid DC circuit breakers can be broadly categorized into two types: natural commutation type and forced commutation type. The forced commutation type can be further subdivided into impedance commutation type and power source commutation type. The interruption principle of a hybrid DC circuit breaker is shown in FIG. 8. During the normal current-carrying phase, a main branch provides a low-impedance conduction path for a load current. In the fault clearance phase, the first step is to open a fast mechanical switch in the main branch, followed by transferring the fault current to the power electronic switch in a transfer branch, and finally, the current is turned off by using a fully-controlled power electronic device. For the hybrid DC circuit breakers, the power electronic switch serves as the core component for turning off the fault currents. Therefore, it is crucial to construct a cost-effective bidirectional power electronic switch topology through the coordinated operation of multiple power electronic devices, buffer circuits, and MOVs. In engineering practice, three commonly used types of bidirectional power electronic switch topologies are: anti-series topology (using inverse-conducting devices), anti-parallel topology (using inverse-blocking devices), and diode bridge topology. Inverse-conducting devices represent the mainstream form of power devices currently. Most fully-controlled devices do not inherently possess reverse current-carrying and voltage-blocking capabilities. Hence, they typically require an anti-parallel diode to form an inverse-conducting structure. By further anti-serially connecting the inverse-conducting structure, a module with bidirectional current-carrying and blocking capabilities can be realized, which is the mainstream solution for bidirectional power electronic switches in the early stages. Inverse-blocking devices are less commonly applied; generally, only derivative devices of thyristors can achieve bidirectional voltage blocking. If a power electronic device inherently possesses the bidirectional voltage-blocking capability, then simply connecting two such devices in reverse parallel is sufficient to realize bidirectional controllability of the power electronic switch. If the cost of four diode bridge arms is sufficiently low compared to that of a single fully-controlled device, the diode bridge power electronic switch is considered an economical topology.

Expandably, in the bidirectional power electronic interruption assembly, the fully-controlled device employs the power BJT device and the drive circuit.

Meanwhile, in the medium- and high-voltage domains, the power electronic switch used in the DC circuit breakers is typically composed of tens or even hundreds of fully-controlled power electronic devices connected in series or modularly cascaded. The cost of the power electronic switch accounts for 50% or above of the total primary cost of the DC circuit breaker. The power electronic switches not only need to rapidly turn off fault currents but must also be capable of withstanding extremely high switching overvoltages and absorbing a significant amount of inductive energy generated during system short circuits. Therefore, MOV elements are widely utilized to limit the overvoltages generated when the power electronic switches turn off the current, thereby protecting the power electronic devices from damage.

N represents the number of fully-controlled switching devices connected in series within the power electronic switch. L denotes the equivalent inductance of the DC system. U_{DC} represents the voltage of the DC system, i_{DC} represents the current of the DC system, Uᵣₑₛ represents the residual protection voltage of the MOV, U_{1mA} represents the 1 mA reference voltage of the MOV, Vₘₐₓ represents the maximum withstand voltage of the power electronic switch, V_{DC} represents the rated DC voltage borne by the power electronic switch device, Rap represents the charge rate of the MOV, and K represents the residual voltage ratio of the MOV. The charge rate of the MOV is defined as:

$${R}_{ap} = \frac{{V}_{D C}}{{U}_{1 m A}} ,$$

and the residual voltage ratio of the MOV is defined as:

$$K = \frac{{U}_{r e s}}{{U}_{1 mA}} .$$

Since the hybrid DC circuit breaker needs to suppress the overvoltage generated during the fault current interruption process and absorb the substantial inductive energy in the DC system when interrupting the fault current, it is necessary to parallelly connect MOVs across the power electronic switch.

The DC system current equation during the energy dissipation period can be described as follows:

$$N \cdot {U}_{r e s} - {U}_{D C} = L \cdot \frac{d {i}_{D C}}{d t} .$$

During this process, as long as the condition N·Uᵣₑₛ>U_{DC} is satisfied, the MOV can continuously dissipate the inductive energy in the DC system until the DC system current i_{DC} reaches zero. Based on experiences from existing engineering practices, when N·Uᵣₑₛ≥1.5U_{DC}, the energy dissipation rate of the MOV can meet the overall requirements of the DC system for the line fault clearance time.

The basic principles of the present application have been described above in connection with specific embodiments, however, it should be noted that the advantages, effects and the like mentioned in the present application are only examples and not limitations, and these advantages, effects and the like are not to be considered as necessarily being present in the various embodiments of the present application. In addition, the foregoing disclosure of specific details has been presented for purposes of illustration and understanding only, and is not intended to limit the disclosure to the extent that it must be practiced with specific details.

The foregoing description has been presented for purposes of illustration and description. Furthermore, this description is not intended to limit embodiments of the present application to the form disclosed herein. While a number of example aspects and embodiments have been discussed above, those of skill in the art will recognize certain variations, modifications, changes, additions and sub-combinations thereof.

1. A power bipolar junction transistor (BJT) device with single pulse current strong turn-off capability, comprising,
an N-type substrate,
an N-type drift region laminated on the substrate,
a P-type base region laminated on the N-type drift region,
at least one N-type region arranged on the P-type base region,
a collector arranged on the N-type substrate as a power lead-out electrode,
an emitter arranged on the N-type region as a power lead-out electrode,
a base arranged on the P-type base region without contacting the N-type region as a control lead-out electrode, and
a drive circuit connected with the base to control the turn-on and turn-off of a power BJT device.

2. The power BJT device with single pulse current strong turn-off capability according to claim 1, wherein the drive circuit operates according to an external control signal, which is an optical signal or an electrical signal.

3. The power BJT device with single pulse current strong turn-off capability according to claim 1, wherein the drive circuit comprises a base injection circuit and a base reverse bias circuit connected in parallel.

4. The power BJT device with single pulse current strong turn-off capability according to claim 3, wherein when the power BJT device is subjected to a voltage greater than a threshold voltage, if the base injection circuit is connected and the base reverse bias circuit is disconnected, the power BJT device enters a turn-on state; if the base injection circuit is disconnected and the base reverse bias circuit is disconnected, the power BJT device enters a turn-off state; if the base injection circuit is disconnected and the base reverse bias circuit is connected, the power BJT device remains in the turn-off state with enhanced blocking voltage capability.

5. The power BJT device with single pulse current strong turn-off capability according to claim 3, wherein the base injection circuit and the base reverse bias circuit are restricted from being simultaneously connected.

6. The power BJT device with single pulse current strong turn-off capability according to claim 3, wherein the base injection circuit comprises,
a pre-storage capacitor C1 and a device Q1 connected in series, the device Q1 being either a half-controlled power electronic device or a fully-controlled power electronic device,
a pre-storage capacitor C2 and a device Q2 connected in series, which are connected in parallel with the pre-storage capacitor C1 and the device Q1 connected in series, the device Q2 being a fully-controlled power electronic device,
a diode D1, connected in parallel with the pre-storage capacitor C1 and the device Q1 connected in series,
an inductor L1, connected with the device Q1, the device Q2 and the diode D1,
a diode D2 and a resistor R1 connected in series, which are connected in parallel with the inductor L1, and
a device Q3, connected in series with the inductor L1, the device Q3 being a fully-controlled power electronic device.

7. The power BJT device with single pulse current strong turn-off capability according to claim 6, wherein the base reverse bias circuit comprises a device Q4, a resistor R2 and a pre-storage capacitor C3 connected in series, the device Q4 being either a half-controlled power electronic device or a fully-controlled power electronic device.

8. The power BJT device with single pulse current strong turn-off capability according to claim 7, wherein the fully-controlled power electronic device comprises an IGBT or MOSFET.

9. A hybrid direct current circuit breaker, comprising the power BJT device with single pulse current strong turn-off capability according to claim 1.

10. An interruption method for the power BJT device with single pulse current strong turn-off capability according to claim 7, comprising the steps of,
connecting the device Q1 and the device Q3 simultaneously, allowing the pre-storage capacitor C1 to discharge through the inductor L1, enabling a base drive current to rise to a predetermined base injection current maximum threshold;
when a current of the inductor L1 reaches a half-wave peak, disconnecting the device Q1 and the device Q2 while keeping the device Q3 connected to enable freewheeling of the base drive current through the diode D1,
when a current of the inductor L1 falls to the lowest base injection current minimum threshold required for the power BJT device to remain in the turn-on state, keeping the device Q1 disconnected and the device Q2 connected, allowing the pre-storage capacitor C2 to discharge through the inductor L1, enabling the base drive current to slowly rise to the base injection current maximum threshold;
repeating switching several times according to the fluctuating state of the base drive current during the period that the power BJT device remains in the turn-on state; and
when the power BJT device turns off the current, disconnecting the device Q1, the device Q2, and the device Q3, connecting the device Q4, allowing the pre-storage capacitor C3 to continuously applies a reverse bias voltage at the base through the resistor R2 and the device Q4, enabling the current of the inductor L1 to be dissipated through the diode D2 and the resistor R1.

11. The hybrid direct current circuit breaker of claim 9, wherein the drive circuit operates according to an external control signal, which is an optical signal or an electrical signal.

12. The hybrid direct current circuit breaker of claim 9, wherein the drive circuit comprises a base injection circuit and a base reverse bias circuit connected in parallel.

13. The hybrid direct current circuit breaker of claim 12, wherein when the power BJT device is subjected to a voltage greater than a threshold voltage, if the base injection circuit is connected and the base reverse bias circuit is disconnected, the power BJT device enters a turn-on state; if the base injection circuit is disconnected and the base reverse bias circuit is disconnected, the power BJT device enters a turn-off state; if the base injection circuit is disconnected and the base reverse bias circuit is connected, the power BJT device remains in the turn-off state with enhanced blocking voltage capability.

14. The hybrid direct current circuit breaker of claim 12, wherein the base injection circuit and the base reverse bias circuit are restricted from being simultaneously connected.

15. The hybrid direct current circuit breaker of claim 12, wherein the base injection circuit comprises,
a pre-storage capacitor C1 and a device Q1 connected in series, the device Q1 being either a half-controlled power electronic device or a fully-controlled power electronic device,
a pre-storage capacitor C2 and a device Q2 connected in series, which are connected in parallel with the pre-storage capacitor C1 and the device Q1 connected in series, the device Q2 being a fully-controlled power electronic device,
a diode D1, connected in parallel with the pre-storage capacitor C1 and the device Q1 connected in series,
an inductor L1, connected with the device Q1, the device Q2 and the diode D1,
a diode D2 and a resistor R1 connected in series, which are connected in parallel with the inductor L1, and
a device Q3, connected in series with the inductor L1, the device Q3 being a fully-controlled power electronic device.

16. The hybrid direct current circuit breaker of claim 15, wherein the base reverse bias circuit comprises a device Q4, a resistor R2 and a pre-storage capacitor C3 connected in series, the device Q4 being either a half-controlled power electronic device or a fully-controlled power electronic device.

17. The hybrid direct current circuit breaker of claim 16, wherein the fully-controlled power electronic device comprises an IGBT or MOSFET.

18. The method of claim 10, wherein the fully-controlled power electronic device comprises an IGBT or MOSFET.
